(19) United States
(12) Patent Application Publication
(10) Pub. No.: US 2018/0287284 A1
(43) Pub. Date: Oct. 4, 2018

(54) CONTACT SOCKET

(71) Applicant: TKR SPEZIALWERKZEUGE GMBH, GEVELSBERG (DE)

(72) Inventor: Torsten Kreischer, Wetter (DE)

(21) Appl. No.: 15/943,879

(22) Filed: Apr. 3, 2018

(30) Foreign Application Priority Data
Apr. 3, 2017 (DE) 10 2017 107 142.3

(51) Int. Cl. H01R 13/187; H01R 13/11; H01R 12/71; H01R 31/06; H05K 3/34

(52) U.S. Cl. CPC H01R 13/187; H01R 13/113; H05K 3/34; H01R 31/06; H01R 12/716

(57) ABSTRACT

A contact socket for receiving a plug unit with at least one electrically conductive contact pin. The contact socket has a circuit board that can be contacted with the contact pin and a socket opening that receives a contact pin housing. In order to provide a contact socket in which the contacting of the contact pin and the circuit board is substantially independent of plug-in cycles, a contact element which projects from the base of the socket opening into the socket opening is arranged on the circuit board and can be brought into engagement with an end surface of the contact pin. The contact element is configured as a compression spring body with a variable length in the direction of the circuit board.

### CROSS-REFERENCE TO RELATED APPLICATION

This application claims the priority, under 35 U.S.C. § 119, of German patent application DE 10 2017 107 142.3, filed Apr. 3, 2017; the prior application is herewith incorporated by reference in its entirety.

### BACKGROUND OF THE INVENTION

### Field of the Invention

The invention relates to a contact socket for receiving a plug unit that has at least one electrically conductive contact pin, with
a circuit board that can be contacted with the contact pin, and
a socket opening that receives a contact pin housing.

Contact sockets of the aforementioned type are used in particular in motor vehicles, inter alia, to interconnect various electronic vehicle components. The contact sockets and the plug units that connect with them are matched to each other. Connector contacts for the contact pins of the plug units are arranged in the interior of the contact socket, and an electrically conductive connection is established by the connector contacts when the plug unit and the contact socket are in the assembled state. The connector contacts are arranged on a circuit board within the contact socket or are connected to the circuit board, for example. The shape of the contact socket housing and the plug unit housing are matched to each other in such a way that a reliable arrangement of the housings against each other is ensured when the contact socket and plug unit are in the assembled state.

In the assembled state of the contact socket and the plug unit, it is also necessary to ensure that the contact pins are connected with the associated contacts on the contact socket in an electrically conductive way. A faulty or inadequate contact leads to transmission problems over the connection established by the contact socket and the plug unit, which can lead to disruptions of individual systems in the motor vehicle or even to a complete breakdown of the motor vehicle.

This kind of disruption can occur in particular when the plug connection has been disconnected multiple times, since known contact sockets of the aforementioned type have the disadvantage that they ensure a reliable electrically conductive connection in the assembled state of the plug unit and contact socket only over a small number of plug cycles. Due to repeated disconnections of the contact socket and plug unit, especially after a motor vehicle repair, a disruption in the electrically conductive connection can occur as a result of the number of plug cycles involved. Moreover, the known contact sockets have the disadvantage that, on the side of the circuit board facing away from the contact pins, they require a significant amount of installation space for those components that secure the contact pins in their position on the contacts of the circuit board.

### SUMMARY OF THE INVENTION

Proceeding from this, the invention addresses the object of providing a contact socket in which the contacting of the contact pin and the circuit board is substantially independent of the plug cycles.

With the above and other objects in view there is provided, in accordance with the invention, a contact socket for receiving a plug unit having at least one electrically conductive contact pin. The contact socket comprises:

a circuit board to be contacted with the contact pin;

a socket opening configured to receive a contact pin housing, the socket opening having a base;

a contact element disposed on the circuit board and projecting from the base into the socket opening, the contact element being configured for engagement with an end surface of the contact pin;

the contact element being a compression spring body having a variable length in a direction of the circuit board.

Characteristic for the contact socket according to the invention is that a contact element that projects from the base of the socket opening into the socket opening is arranged on the circuit board and can be brought into engagement with an end surface of the contact pin of a plug unit and that the contact element is configured as a compression spring body with a variable length in the direction of the circuit board (i.e., in a direction substantially perpendicular to the circuit board). The term “variable length” is understood to mean the suitability of the compression spring body to elastically modify its extent in the longitudinal direction. An elastic deformation occurs by the assembly of the plug unit on the contact socket, during which the compression spring body is elastically deformed by the contact pin in the direction of the circuit board.

According to the invention, the contact on the circuit board that is to be contacted with the contact pin of the plug unit is connected to a contact element which is configured as a compression spring body, the free end of which, lying opposite the circuit board, projects into the socket opening from the base of a socket opening of the contact socket.

The configuration of the contact element as a compression spring body is such that, in a connection between the contact socket and plug unit, one or more contact pins of the plug unit abut the associated compression spring bodies with their end surfaces. In the assembled position, the elastic deformation of the compression spring body that is brought about by the contact pins causes a frictional contact of the compression spring body against the front sides of the contact pins. The contact pins in this case can have essentially any desired shape, e.g. be configured as a flat plug or cylindrical pins, wherein, if possible, the compression spring bodies preferably have correspondingly configured contact surfaces so that, when assembled, the front sides of the contact pins come to reliably abut the compression spring bodies and they elastically deform so that their longitudinal extent is modified in the direction of the contact pins.

The configuration of the contact pins as compression spring bodies the length of which can be modified in the longitudinal direction of the socket openings or respectively in the direction of the circuit board makes it possible to utilize the displacement which occurs as a result of the movement of the contact pins when the plug unit and the contact socket are connected to elastically deform the compression spring bodies so that the restoring energy ensures that the contact pins reliably rest against the compression spring bodies that are connected to the circuit board. Designing the compression spring bodies in such a way that they are deformed only in the elastic range during a contacting of the contact socket and plug unit ensures in an especially reliable way that a reliable contact is established regardless of the plug cycle.

The configuration of the compression spring body such that it undergoes an elastic deformation when the contact pin is introduced into the contact socket and when the contact socket and plug unit are connected can generally be freely selected. Thus the compression spring body can be designed as a helical compression spring, for instance, which is arranged on the circuit board at one end and is configured at the other end for contact with the contact pin of the plug unit, which causes a deformation of the helical compression spring in the elastic range when the plug unit and contact socket are in the assembled position.

According to an especially advantageous embodiment of the invention, however, it is provided that the compression spring body has at least one deformation section, which is inclined relative to the longitudinal axis of the socket opening. According to this embodiment of the invention it is provided that the compression spring body has at least one section extending transversely to the longitudinal axis of the socket opening, i.e. it runs at an angle smaller than 90° and larger than 0° to the longitudinal axis. The longitudinal axis of the socket opening corresponds to the axis along which the contact pin moves when the plug unit is assembled on the contact socket. The use of an inclined deformation section provides an especially simple way to ensure an elastically deformable compression spring body, wherein, in interacting with the contact pin, the inclination of the deformation section relative to the longitudinal axis of the socket opening is usually increased. In a particularly simple embodiment, the compression spring body can be configured in a Z shape, for example, wherein the body abuts the circuit board at one end and is configured for contact with the contact pin at the other end.

In a corresponding embodiment of the compression spring body, it is generally very easy to establish contact between the contact pin and the compression spring body. According to an especially advantageous embodiment of the invention, however, it is provided that the free end of the compression spring body has a contact section that runs substantially perpendicular to the longitudinal axis of the socket opening. The arrangement of a contact section running transversely to the direction in which the contact pin is inserted into the socket opening is especially reliable in ensuring that the front side of the contact pin reliably abuts the compression spring body. In a contact pin that is configured as a flat plug, the use of e.g. a contact section running transversely to the longitudinal axis of the socket opening makes possible a wide contact surface between the contact pin and the contact element, so that an electrically conductive connection is reliably established and there is a sufficient abutment of the compression spring body against the contact pin.

Securing the position of the compression spring body within the contact socket and contacting it with the circuit board can be carried out in essentially any desired way. According to an especially advantageous embodiment of the invention, however, it is provided that the compression spring body protrudes through an opening in a socket bottom that forms the base of the socket opening.

According to this embodiment of the invention, the socket opening is delimited by a socket bottom that has openings, through which the one or more compression spring bodies that are connected to the circuit board project. The use of a socket bottom that is provided with openings ensures that the position of the compression spring bodies is reliably secured by the openings. The compression spring bodies are passed through the opening at the edge so that the compression spring bodies are prevented from incorrectly making evasive movements during their interaction with the contact pins. Additionally, this embodiment of the invention also makes possible a reliable securing of the position of the compression spring bodies against the contacts of the circuit board, which is especially preferred to abut on the side of the socket bottom opposite the socket opening, so that the contact socket has a particularly low constructional depth.

The way in which the circuit board is attached to the contact socket can likewise generally be freely selected. According to an especially advantageous embodiment of the invention, however, the circuit board is attached to the socket bottom, in particular is screwed to it. A corresponding embodiment of the invention ensures that the position of the circuit board on the contact socket is reliably ensured, wherein, in the case of the advantageously provided embodiment of the invention in which the compression spring bodies project through openings in the socket bottom, the position of the compression spring bodies within the socket opening can be ensured in an especially reliable way by the attachment of the circuit board to the socket bottom, in particular by a screw connection.

The connection of the contact elements, which are configured as compression spring bodies, to the corresponding contacts on the circuit board can generally be freely selected. For example, they can be electroconductively connected to the contact points on the circuit board by suitable adhesives. According to an especially advantageous embodiment of the invention, however, it is provided that the compression spring bodies are soldered to the circuit board. The soldered connection is particularly simple and cost-effective to produce, and it ensures that the compression spring bodies are electrically contacted with the circuit board in a particularly reliable way.

According to another embodiment of the invention, it is further provided that the circuit board abuts a housing cover. According to this embodiment of the invention, a housing body of the contact socket is enclosed by a housing cover, which directly abuts the circuit board and thus secures it in its position within the contact socket. Moreover, an abutment of the housing cover against the circuit board ensures that the constructional depth of the contact socket is configured especially small, wherein the abutment can also be at one point.

Other features which are considered as characteristic for the invention are set forth in the appended claims.

Although the invention is illustrated and described herein as embodied in a contact socket, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 a first exploded view of a contact socket; and

FIG. 2 a second exploded view of the contact socket in FIG. 1.

### DETAILED DESCRIPTION OF THE INVENTION

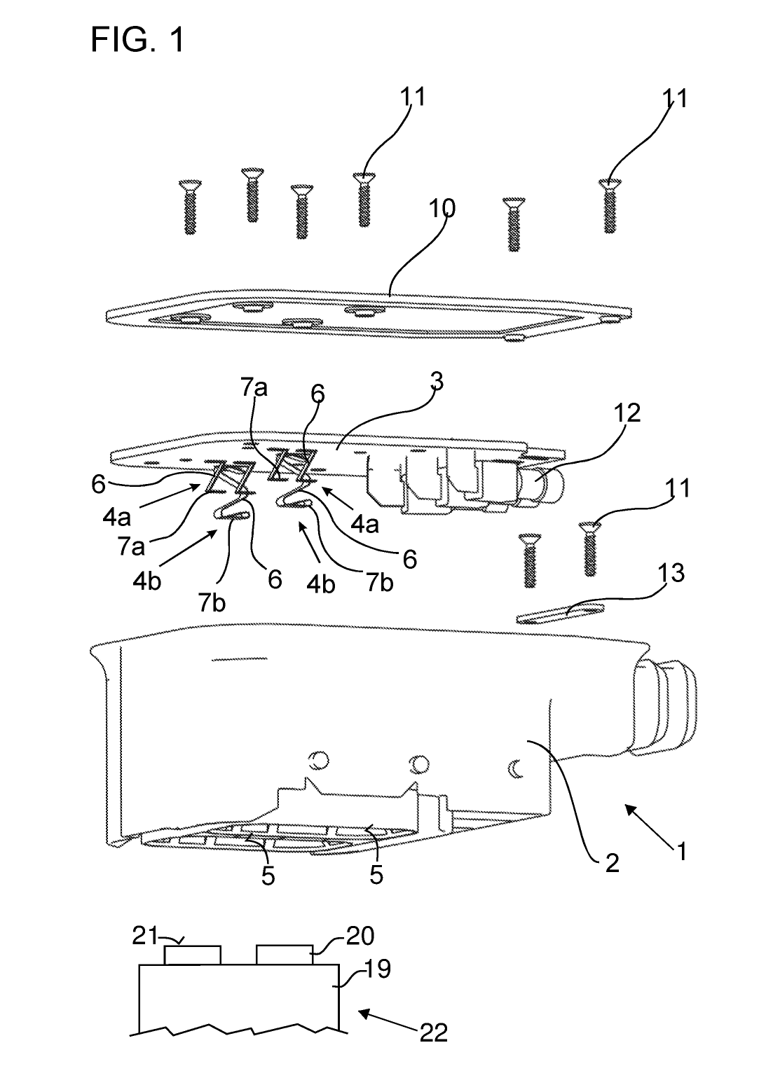

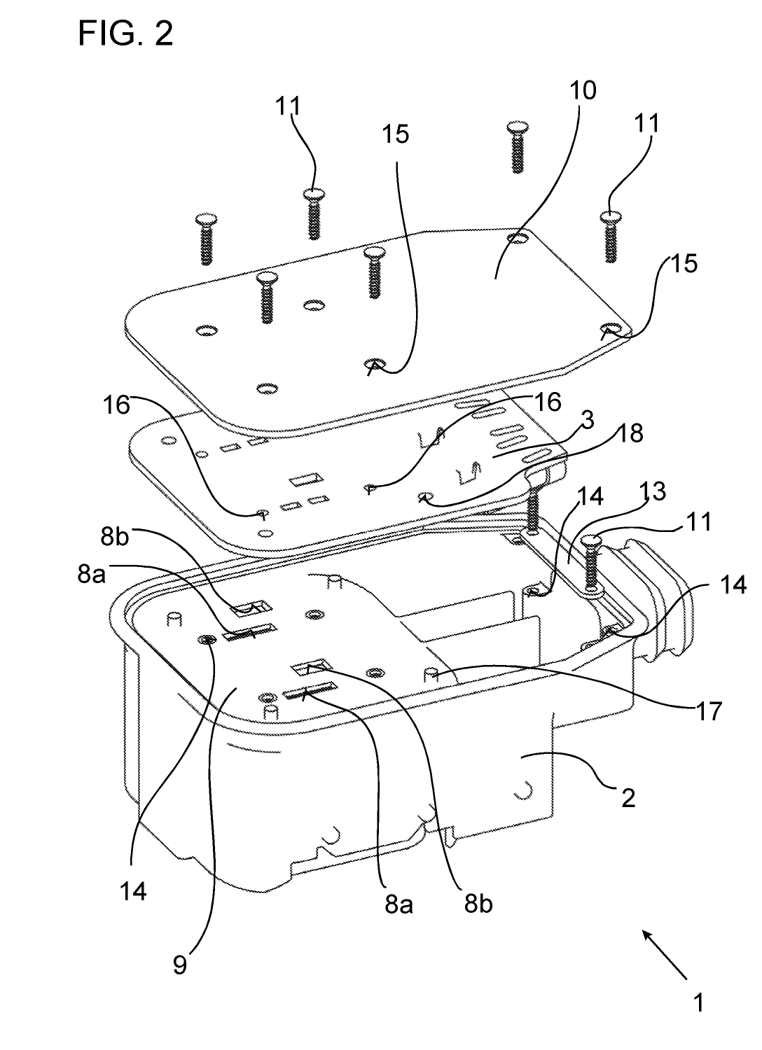

Referring now to the figures of the drawing in detail, there is shown an exemplary embodiment of a contact socket 1, illustrated from two different viewpoints in FIGS. 1 and 2, respectively, each in an exploded view.

The contact socket 1 has a socket housing 2, which in the embodiment shown has two socket openings 5 for a plug unit 22, which is only illustrated highly schematically, wherein the socket openings 5 then serve to receive a contact pin housing 19 of the plug unit 22. The plug unit 22 is also illustrated with two exemplary contact pins 20 that have an end surface 21 which forms a contact surface.

The socket openings 5 are delimited in the directions of insertion of the plug unit by a socket bottom 9 or socket floor 9, which forms the base of the socket opening 5. That is, the socket bottom 9 bounds the socket opening 5 opposite an insertion opening into the socket opening. The socket bottom 9 has openings 8a, 8b, which serve to receive compression spring bodies 4a, 4b that are configured as contact elements and that are connected to a circuit board 3 by their ends lying opposite the free ends. The circuit board 3 abuts the socket bottom 9 on the side opposite the socket opening 5, wherein studs 17 on the socket bottom 9 project through stud slots 18 on the circuit board 3 when the circuit board 3 is in the assembled state on the socket bottom 9.

Each of the compression spring bodies 4a, 4b, which are soldered onto provided contacts on the circuit board 3, has on its free end a contact section 7a, 7b that runs substantially perpendicular to the longitudinal axis of the socket opening 5. The contact sections 7a, 7b are configured to correspond with the front sides of the contact pins of the plug unit, not shown here, in order to ensure a reliable abutment against each other. When the plug unit is in the assembled state on the contact socket 1, the contact pins displace the contact sections 7a, 7b in the direction of the circuit board 3, wherein deformation sections 6 of the compression spring bodies 4a, 4b, which are arranged in the area between the circuit board 3 and the contact sections 7a, 7b, are elastically deformed. As a result, the longitudinal extent of the compression spring bodies 4a, 4b is reduced in the longitudinal axial direction of the socket openings. The deformation of the compression spring bodies 4a, 4b that is brought about by the contact pins during the assembly of the plug unit on the contact socket 1 is elastic, and so the resilient force that accumulates as a result of the elastic deformation ensures a reliable abutment of the compression spring bodies 4a, 4b against the contact pins. In the present embodiment, two different types of compression spring bodies 4a, 4b are arranged on the circuit board 3, wherein compression spring bodies 4a have a Z-shaped configuration and a deformation area 6. By contrast, the compression spring bodies 4b possess a wave-like deformation area 6 with two sections.

In addition to the studs 17, the circuit board 3 is secured to the socket bottom 9 by screws 11, wherein the screws 11 extend through bore holes 15 in the housing cover 10 as well as openings 16 in the circuit board 3 and are screwed into screw slots 14 in the socket bottom 9. A supplemental securing of the position of the circuit board 3 is ensured by further screws 11, which extend through bore holes 15 in the housing cover 10 into screw slots 14 in the socket housing 2. A strain relief element 13 serves to relieve strain on a cable that is connected to the circuit board 3 by flat plug sockets 12 and that is not shown here, the strain relief element being clamped in place by screwing screws 11 into further screw slots 14 on the socket housing 2.

The following is a summary list of reference numerals and the corresponding structure used in the above description of the invention:
1 Contact socket
2 Socket housing
3 Circuit board
4a, 4b Contact element/compression spring body
5 Socket opening
6 Deformation section
7a, 7b Contact section
8a, 8b Opening
9 Socket bottom
10 Housing cover
11 Screws
12 Flat plug socket
13 Strain relief element
14 Screw slots
15 Bore holes
16 Openings
17 Studs
18 Stud slot
19 Plug unit
20 Contact pin
21 End surface
22 Plug unit

1. A contact socket for receiving a plug unit having at least one electrically conductive contact pin with an end surface, the contact socket comprising:
a circuit board to be contacted with the contact pin;
a socket opening configured to receive a contact pin housing, the socket opening having a base;
a contact element disposed on the circuit board and projecting from the base into the socket opening, the contact element being configured for engagement with the end surface of the contact pin;
the contact element being a compression spring body having a variable length in a direction of the circuit board.

2. The contact socket according to claim 1, wherein the compression spring body has at least one deformation section that is inclined relative to a longitudinal axis of the socket opening.

3. The contact socket according to claim 1, wherein the compression spring body has a free end formed as a contact section that runs substantially perpendicular to a longitudinal axis of the socket opening.

4. The contact socket according to claim 1, wherein the compression spring body protrudes through an opening formed in a socket bottom that forms the base of the socket opening.

5. The contact socket according to claim 1, wherein the circuit board is attached to the socket bottom.

6. The contact socket according to claim 5, wherein the circuit board is screwed to the socket bottom.

7. The contact socket according to claim 1, wherein the compression spring body is soldered to the circuit board.

8. The contact socket according to claim 1, which comprises a housing cover opposite the opening, wherein the circuit board abuts the housing cover.
